(19) United States
(12) Patent Application Publication
(10) Pub. No.: US 2012/0235131 A1
(43) Pub. Date: Sep. 20, 2012

(54) ORGANIC ELECTROLUMINESCENCE ELEMENT, MANUFACTURING METHOD THEREOF, AND ORGANIC ELECTROLUMINESCENCE DISPLAY DEVICE

(75) Inventor: Ken Okamoto, Osaka (JP)

(73) Assignee: Sharp Kabushiki Kaisha, Osaka-shi ,Osaka (JP)

(21) Appl. No.: 13/512,007

(22) PCT Filed: Oct. 12, 2010
(86) PCT No.: PCT/JP2010/067885

§ 371 Date: May 24, 2012

(30) Foreign Application Priority Data
Nov. 27, 2009 (JP) 2009-270823

(51) Int. Cl. H01L 51/54; H01L 51/40

(52) U.S. Cl. 257/40; 438/46; 257/E51.026

(57) ABSTRACT

An organic EL element (1) of the present invention includes an emission layer (5) which is made of a host material having a highest occupied molecular orbital shallower than a highest occupied molecular orbital (8) of an organic light emitting material in the emission layer (5) (|HOMO of host material|<|HOMO of organic light emitting material|) or a host material having a lowest unoccupied molecular orbital deeper than a lowest unoccupied molecular orbital (9) of the organic light emitting material (|LUMO of host material|>|LUMO of organic light emitting material|). This makes it possible to keep the hole mobility and the electron mobility high in the host material of the emission layer (5), and therefore the hole and the electron can be efficiently transported to the emission layer (5). As a result, both the hole and the electron can be confined within the emission layer (5), and therefore the hole becomes more likely to recombine with the electron. On this account, the internal quantum yield rate can be improved, the luminous efficiency can be improved, and a driving voltage can be reduced.

### TECHNICAL FIELD

The present invention relates to (i) an organic electroluminescence element which achieves high luminance, high efficiency, and long life duration, (ii) a method for manufacturing the organic electroluminescence element, and (iii) an organic electroluminescence display device.

### BACKGROUND ART

In recent years, needs for thin flat panel displays (FPD) are increasing, instead of cathode-ray tube display devices which have been predominantly used conventionally. Examples of such FPDs encompass various kinds of displays such as a non-self-luminous liquid crystal display (LCD), a self-luminous plasma display panel (PDP), an inorganic electroluminescence (inorganic EL) display, and an organic electroluminescence (organic EL) display.

Among those, the organic EL display has been actively studied and developed because an element (organic EL element), having various properties, is used in the organic EL display for carrying out a display. Examples of such properties encompass a thin body, lightweight, being driven at a low voltage, high luminance, and self-luminous property.

An organic EL element includes (i) a pair of electrodes (anode and cathode), (ii) a substrate, and (iii) an organic layer which at least includes an emission layer. The organic layer is provided between the pair of electrodes. The emission layer is made of a host material which is doped with an organic light emitting material. In general, there is provided between the emission layer and the anode a layer such as (i) a hole injection layer, which is formed by doping the host material with an acceptor, (ii) a hole transport layer, which is formed by doping the host material with an acceptor, or (iii) a stacked film of the hole injection layer and the hole transport layer. Moreover, there is provided between the emission layer and the cathode a layer such as (i) an electron injection layer, which is formed by doping the host material with a donor, (ii) an electron transport layer, which is formed by doping the host material with a donor, or (iii) a stacked film of the electron transport layer and the electron injection layer.

According to the organic EL element, when voltages are applied to respective of the anode and the cathode, a positive hole is injected to the organic layer from the anode and an electron is injected to the organic layer from the cathode. The positive hole and the electron, injected from the respective electrodes, are recombined with each other in the emission layer so as to generate an exciton. The organic EL element emits light by utilizing light discharged when the exciton is deactivated.

In general, a phosphorescent material or an organic light emitting material such as a fluorescent material is used in the emission layer. An organic EL element utilizing a phosphorescent material brings about advantages such as high luminous efficiency and long emission lifetime. Therefore, particularly in recent times, such an organic EL element, including an emission layer made of a phosphorescent material, is becoming popular. Moreover, an organic EL element is under development to which a phosphorescent material, which has maximum of 100% of internal quantum yield rate, is added in order to reduce power consumption of the organic EL element.

A phosphorescent material, which has maximum of 100% of internal quantum yield rate, is added to each of organic EL elements which emit respective red light and blue light. However, such a phosphorescent material having maximum of 100% of internal quantum yield rate cannot be added to an organic EL element which emits blue light. Therefore, a fluorescent material, which has maximum of 25% of internal quantum yield rate, is used in the organic EL element which emits blue light.

In order for an organic EL element to emit blue light, higher energy is required, as compared to each of red light and green light. Moreover, in order to obtain the energy from excited triplet energy (T₁), all excited triplet energy, electrons, and positive holes need to be confined within a phosphorescent material. In view of this, it is necessary to secure drastically large difference between a highest occupied molecular orbital (HOMO) and a lowest unoccupied molecular orbital (LUMO) not only in a material of the emission layer but also in its peripheral materials. However, since the emission layer has a HOMO and a LUMO which are widely different from each other, it is difficult to employ a material, as a host material of the emission layer, (i) in which molecules conjugate and interact and (ii) which has a high carrier mobility. On this account, in a case where a blue phosphorescent material is used, there is a problem that luminous efficiency is low in spite of a high driving voltage being required.

FIG. 9 illustrates a concrete example of a conventional organic EL element 31 in which a blue phosphorescent material is used. FIG. 9 is an energy diagram illustrating layers constituting the conventional organic EL element 31 in which a blue phosphorescent material is used. In the configuration shown in FIG. 9, NPB (HOMO=5.5 eV, LUMO=2.4 eV) is used as a host material of a hole injection layer 33, mCP (HOMO=5.9 eV, LUMO=2.4 eV) is used as a host material of a hole transport layer 34, and 3TPYMB (HOMO=6.8 eV, LUMO=3.3 eV) is used as a host material of an electron transport layer 36. As a phosphorescent material in an emission layer 35, FIr6 (HOMO=6.1 eV, LUMO=3.1 eV) is used. In order for positive holes and electrons to be confined within the FIr6, UGH2 (HOMO=7.2 eV, LUMO=2.8 eV), whose HOMO and LUMO are widely different from each other, is used as a host material of the emission layer 35. However, since the UGH2 has the HOMO and LUMO widely different from each other, the UGH2 has a low electron mobility and a low hole mobility. This prevents efficient transportation of positive holes from the hole transport layer 34 to the emission layer 35. Similarly, electrons cannot be efficiently transported from the electron transport layer 36 to the emission layer 35. For the reasons above, the organic EL element 31, in which the blue phosphorescent material is thus used, has the problem that luminous efficiency is low in spite of a high driving voltage being required.

In view of this, efforts have been made for improving luminous efficiency of an organic EL element in which a blue phosphorescent material is used. For example, Non Patent Literature 1 discloses an organic EL element including two emission layers. The following concretely describes the organic EL element with reference to FIG. 10. FIG. 10 is an energy diagram illustrating layers constituting an organic EL 21 having a two-layered emission layer 25. Non Patent Literature 1 discloses the organic EL element 21 including an organic layer which is provided between a pair of electrodes by forming a hole injection layer 23, a first emission layer 25a, a second emission layer 25b, and an electron injection layer 27 in this order (see FIG. 10). According to Non Patent Literature 1, DTASi (HOMO=5.6 eV, LUMO=2.2 eV) is used as a host material of the hole injection layer 23, and Bphen (HOMO=6.4 eV, LUMO=3.0 eV) is used as a host material of the electron injection layer 27. Moreover, 4CzPBP (HOMO=6.0 eV, LUMO=2.5 eV) is used as a host material of the first emission layer 25a, and PPT (HOMO=6.6 eV, LUMO=2.9 eV) is used as a host material of the second emission layer 25b. Each of the first emission layer 25a and the second emission layer 25b is doped with FIrpic (HOMO=5.8 eV, LUMO=2.9 eV) as a blue phosphorescent material. This makes it possible to obtain the organic EL element 21 in which a difference is small between a HOMO and a LUMO in each of the first emission layer 25a and the second emission layer 25b. This allows the emission layer 25 of the organic EL element 21 to have a molecular configuration in which π conjugations are relatively spread, and therefore hole and electron mobilities in the emission layer 25 can be improved. It is therefore possible to obtain an organic EL element 21 which can be driven at a low voltage of 4.6 V at 1000 cd/m² and has high luminous efficiency of 22 cd/A at 1000 cd/m².

### CITATION LIST

### Non Patent Literature

### Non Patent Literature 1

Applied Physics Letters 94, 083506, 2009

### Non Patent Literature 2

“Chemistry of Electron Transfer—Introduction to Electrochemistry” written by Tadashi Watanabe and Seiichiroh Nakabayashi, compiled by The Chemical Society of Japan, Asakura Publishing Co. Ltd, September, 2005

### SUMMARY OF INVENTION

### Technical Problem

According to the organic EL element 21 disclosed in Non Patent Literature 1, when an electron is transported from the electron injection layer 27 to the second emission layer 25b, the electron is transported to a luminescent dopant (FIrpic). However, the organic EL element 21 of Non Patent Literature 1 has a configuration in which the electron is easily transported to the first emission layer 25a from the luminescent dopant. According to the configuration, therefore, positive holes do not recombine with electrons at an interface between the first emission layer 25a and the second emission layer 25b. This causes a reduction in probability of recombination of positive holes and electrons. That is, internal quantum yield rate will be decreased.

Moreover, according to the organic EL element 21 of Non Patent Literature 1, the FIrpic, by which sky blue light is emitted, is used as the phosphorescent material of each of the first emission layer 25a and the second emission layer 25b. The FIrpic has a HOMO 28 and a LUMO 29, that is, a difference is small between the HOMO 28 and the LUMO 29 of the FIrpic. This makes it possible to obtain an organic EL element which achieves high luminous efficiency in spite of a low driving voltage being required. This shows that, in a case where a phosphorescent material, by which deep blue light is emitted, is used, it is necessary to use a host material having a HOMO and a LUMO which are widely different from each other, because a difference is large between a HOMO and a LUMO of the phosphorescent material by which deep blue light is emitted. Therefore, the problem has remained that luminous efficiency is low in spite of a high driving voltage being required.

The present invention is accomplished in view of the problem, and its object is to provide (i) an organic EL element which can be driven at a low voltage and has high luminous efficiency and (ii) a method for manufacturing the organic EL element.

### Solution to Problem

In order to attain the object, an organic electroluminescence element of the present invention includes: an anode and a cathode; a substrate; and an organic layer, provided between the anode and the cathode, which includes at least an emission layer made of a host material which is doped with an organic light emitting material, the organic layer including: a hole transport layer, provided between the anode and the emission layer, for transporting a positive hole which has been injected to the organic layer from the anode, and an electron transport layer, provided between the cathode and the emission layer, for transporting an electron which has been injected to the organic layer from the cathode, the host material being a hole-transporting material, and the host material and the organic light emitting material having (i) respective highest occupied molecular orbitals (HOMOs) and (ii) respective lowest unoccupied molecular orbitals (LUMOs) which satisfy the following relational expressions (1) and (2):

0 eV<(|HOMO of organic light emitting material|−|HOMO of host material|)≦0.5 eV (1)

|LUMO of host material|<|LUMO of organic light emitting material| (2)

According to the configuration, the host material of the emission layer has the highest occupied molecular orbital shallower than that of the organic light emitting material. This allows prevention of a positive hole, which has been transported via the hole transport layer, from being moved to the electron transport layer. Consequently, positive holes are confined within the emission layer, and therefore the positive holes become more likely to recombine with electrons. This allows a reduction in a voltage required for driving the organic electroluminescence element (organic EL element). Moreover, since the probability of positive holes recombining with electrons in the emission layer is increased, internal quantum yield rate is improved. This allows an improvement in luminous efficiency.

A conventional organic EL element, in which a blue phosphorescent material is used, has a problem that luminous efficiency is low, in spite of a high driving voltage being required. On the other hand, according to the present invention, a positive hole and an electron can be confined within the emission layer, even in a case where a blue phosphorescent material is used. In other words, according to the present invention, it is possible to increase the probability of positive holes recombining with electrons, and therefore internal quantum yield rate of the organic EL element can be improved. This allows an improvement in luminous efficiency.

The organic EL element of the present invention only needs to include at least the three layers, i.e., the hole transport layer, the emission layer, and the electron transport layer. This allows the organic EL element to have a simple layered structure. It is therefore possible to manufacture the organic EL element of the present invention not by a complex manufacturing method but by an easy manufacturing method. Since the organic EL element has the simple layered structure, it is easy to dope the hole transport layer, the electron transport layer, and the like, with dopants.

In order to attain the object, an organic electroluminescence element of the present invention includes: an anode and a cathode; a substrate; and an organic layer, provided between the anode and the cathode, which includes at least an emission layer made of a host material which is doped with an organic light emitting material, the organic layer including: a hole transport layer, provided between the anode and the emission layer, for transporting a positive hole which has been injected to the organic layer from the anode, and an electron transport layer, provided between the cathode and the emission layer, for transporting an electron which has been injected to the organic layer from the cathode, the host material being an electron-transporting material, and the host material and the organic light emitting material having (i) respective highest occupied molecular orbitals (HOMOs) and (ii) respective lowest unoccupied molecular orbitals (LUMOs) which satisfy the following relational expressions (6) and (7):

0 eV<(|LUMO of host material|−|LUMO of organic light emitting material|)≦0.5 eV (6)

|HOMO of host material|>|HOMO of organic light emitting material| (7)

According to the configuration, it is not necessarily required to use the host material which has (i) the highest occupied molecular orbital shallower than that of the organic light emitting material and (ii) the lowest unoccupied molecular orbital which is deeper than that of the organic light emitting material. Therefore, both the conditions are not necessarily required to be satisfied, as long as at least one of the two conditions is satisfied. For example, an emission layer can be employed which is made of a host material which has (i) a highest occupied molecular orbital shallower than that of an organic light emitting material and (ii) a lowest unoccupied molecular orbital shallower than that of the organic light emitting material. Alternatively, an emission layer can be employed which is made of a host material which has (i) a lowest unoccupied molecular orbital deeper than that of an organic light emitting material and (ii) a highest occupied molecular orbital deeper than that of the organic light emitting material. As such, it is possible to sufficiently increase probability of positive holes recombining with electrons, provided that any one of the conditions is satisfied. Note, however, that, it is more preferable that both the conditions are satisfied.

In order to attain the object, an organic electroluminescence display device of the present invention includes: display means in which any of the above described organic electroluminescence elements is provided on a thin film transistor substrate.

According to the configuration, the organic electroluminescence display device includes the organic EL element which can be driven at a low voltage and has high luminous efficiency. It is therefore possible to provide a display device which achieves high luminance, high efficiency, and long life duration.

In order to attain the object, a method for manufacturing an organic electroluminescence element of the present invention is a method for manufacturing an organic electroluminescence element which includes an anode and a cathode, a substrate, and an organic layer, provided between the anode and the cathode, which includes at least an emission layer made of a host material which is doped with an organic light emitting material, the method including the steps of: forming the anode on the substrate; forming, on the anode, a hole transport layer for transporting a positive hole which has been injected to the organic layer from the anode; forming the emission layer on the hole transport layer; forming, on the emission layer, an electron transport layer for transporting an electron which has been injected to the organic layer from the cathode; and forming the cathode on the electron transport layer, in the forming of the emission layer, a hole-transporting material being used as the host material, the emission layer being formed by use of the host material and the organic light emitting material having (i) respective highest occupied molecular orbitals (HOMOs) and (ii) respective lowest unoccupied molecular orbitals (LUMOs) which satisfy the following relational expressions (11) and (12):

0 eV<(|HOMO of organic light emitting material|−|HOMO of host material|)≦0.5 eV (11)

|LUMO of host material|<|LUMO of organic light emitting material| (12)

In order to attain the object, a method for manufacturing an organic electroluminescence element of the present invention is a method for manufacturing an organic electroluminescence element which includes an anode and a cathode, a substrate, and an organic layer, provided between the anode and the cathode, which includes at least an emission layer made of a host material which is doped with an organic light emitting material, the method including the steps of: forming the anode on the substrate; forming, on the anode, a hole transport layer for transporting a positive hole which has been injected to the organic layer from the anode; forming the emission layer on the hole transport layer; forming, on the emission layer, an electron transport layer for transporting an electron which has been injected to the organic layer from the cathode; and forming the cathode on the electron transport layer, in the forming of the emission layer, an electron-transporting material being used as the host material, the emission layer being formed by use of the host material and the organic light emitting material having (i) respective highest occupied molecular orbitals (HOMOs) and (ii) respective lowest unoccupied molecular orbitals (LUMOs) which satisfy the following relational expressions (13) and (14):

0 eV<(|LUMO of host material|−|LUMO of organic light emitting material|)≦0.5 eV (13)

|HOMO of host material|>|HOMO of organic light emitting material (14)

With the configuration, it is possible to provide an organic EL element which can be driven at a low voltage and has high luminous efficiency.

For a fuller understanding of the other objects, natures, excellent points, and advantages of the present invention, reference should be made to the ensuing detailed description taken in conjunction with the accompanying drawings.

### ADVANTAGEOUS EFFECTS OF INVENTION

According to the organic electroluminescence element of the present invention, it is possible to reduce (i) positive holes which are moved to the electron transport layer without recombining with electrons and (ii) electrons which are moved to the hole transport layer without recombining with positive holes. This causes positive holes and electrons to be confined within the emission layer, and therefore positive holes become more likely to recombine with electrons. On this account, the internal quantum yield rate is improved, and therefore the luminous efficiency can be improved.

### BRIEF DESCRIPTION OF DRAWINGS

FIG. 1 is an energy diagram illustrating layers constituting an organic electroluminescence element in accordance with an embodiment of the present invention.

FIG. 2 is an energy diagram illustrating layers constituting an organic electroluminescence element in accordance with an embodiment of the present invention.

FIG. 3 is an energy diagram illustrating layers constituting an organic electroluminescence element in accordance with an embodiment of the present invention.

FIG. 4 is a cross-sectional view of an organic electroluminescence element in accordance with an embodiment of the present invention.

FIG. 5 is a view schematically illustrating an organic electroluminescence display device including an organic electroluminescence element in accordance with an embodiment of the present invention.

FIG. 6 is a view schematically illustrating a mobile phone including an organic electroluminescence display device in accordance with an embodiment of the present invention.

FIG. 7 is a view schematically illustrating a television receiver including an organic electroluminescence display device in accordance with an embodiment of the present invention.

FIG. 8 is a view schematically illustrating an illumination device including an organic electroluminescence element in accordance with an embodiment of the present invention.

FIG. 9 is an energy diagram illustrating layers constituting a conventional organic EL element which is doped with a blue phosphorescent material.

FIG. 10 is an energy diagram illustrating layers constituting an organic EL element having a two-layered emission layer.

### DESCRIPTION OF EMBODIMENTS

(Outline of Organic Electroluminescence Element 1)

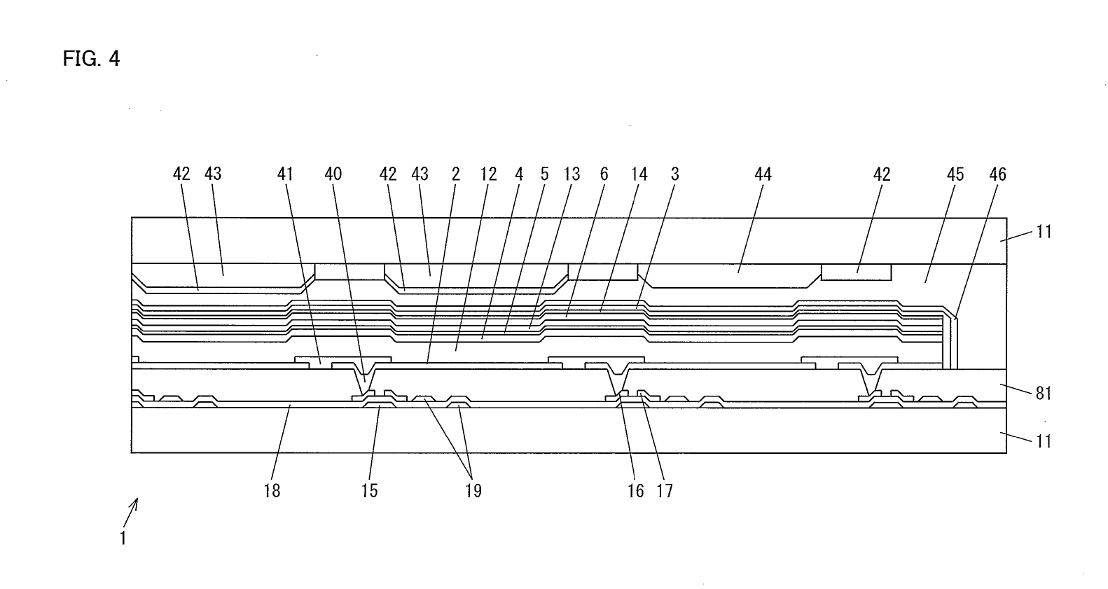

An organic electroluminescence element (hereinafter, referred to as “organic EL element”) of the present embodiment includes (i) a substrate, (ii) a pair of electrodes (i.e., an anode and a cathode), and (iii) an organic layer having an emission layer. The anode, the organic layer, and the cathode are stacked on the substrate in this order so that the organic layer is provided between the anode and the cathode. The following describes, with reference to FIG. 4, a concrete configuration of the organic EL element in accordance with the present embodiment. FIG. 4 is a cross-sectional view illustrating an organic EL element 1.

The organic EL element 1 includes an insulating substrate 1 and a plurality of thin film transistors (TFT) each of which is made up of a gate electrode 15, a drain electrode 16, a source electrode 17, and a gate insulating film 18 (see FIG. 4). The plurality of TFTs are provided on the insulating substrate 11 at predetermined intervals. The organic EL element 1 further includes a plurality of connection wires 19 which are provided so as to connect the insulating substrate 11 with the respective plurality of TFTs.

A planarizing film 81, which has contact holes 40, is provided on the plurality of TFTs. The drain electrodes 15 of the respective plurality of TFTs are electrically connected with respective anodes 2, via the respective contact holes 40. Each edge cover 41 is provided between corresponding adjacent ones of the anodes 2. An organic layer is provided over the anodes 2. The organic layer is made up of a hole injection layer 12, a hole transport layer 4, an emission layer 5, a hole blocking layer 13, an electron transport layer 6, and an electron injection layer 14. Cathodes 3 are provided over the organic layer. The cathodes 3 are covered with an inorganic sealing film 46 so that the anodes 2, the organic layer, and the cathodes 3 are sealed with the inorganic sealing film 46.

On the other hand, a fluorescent layer 43 and a light absorbing layer 42 are provided in this order on an opposite insulating substrate 11. A scatterer layer 44 is also provided on the opposite insulating substrate 11. A resin sealing film 45 is provided between the insulating substrate 11 and the opposite insulating substrate 11.

The organic EL element 1 of the present embodiment is configured such that a difference becomes small between a highest occupied molecular orbital (HOMO) and a lowest unoccupied molecular orbital (LUMO) of a host material of the emission layer 5. Moreover, the organic EL element 1 is configured such that positive holes and electrons can be certainly confined within the emission layer 5. With the configuration, the positive holes become more likely to recombine with the electrons, while keeping high the mobilities of the positive holes and the electrons in the organic layer. This will be described below in detail.

(Configuration of Organic Layer)

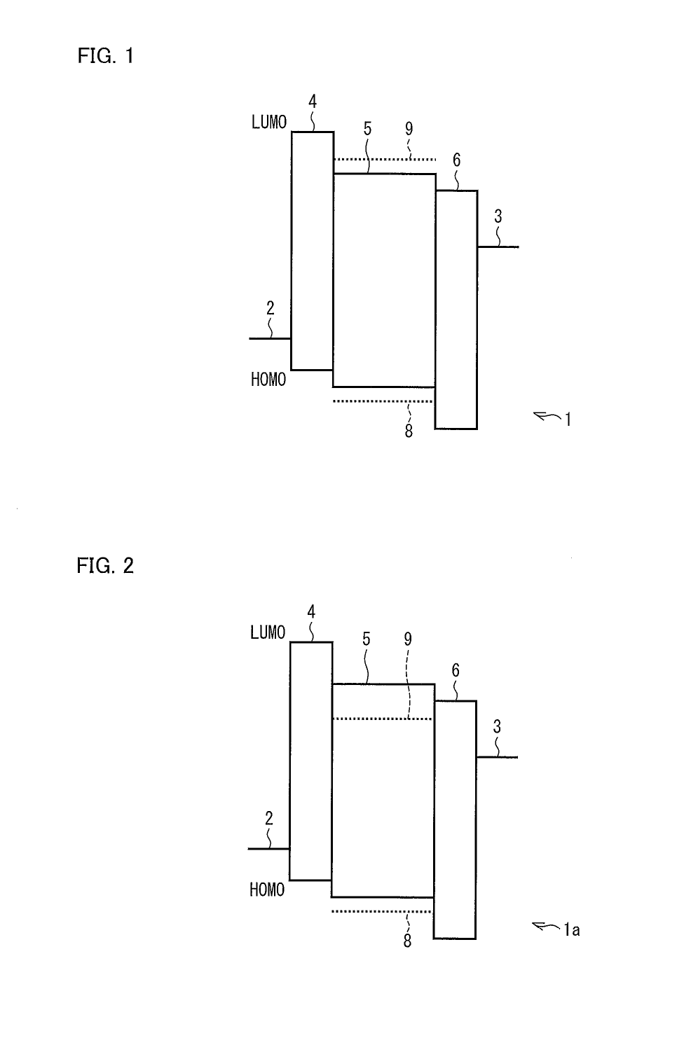

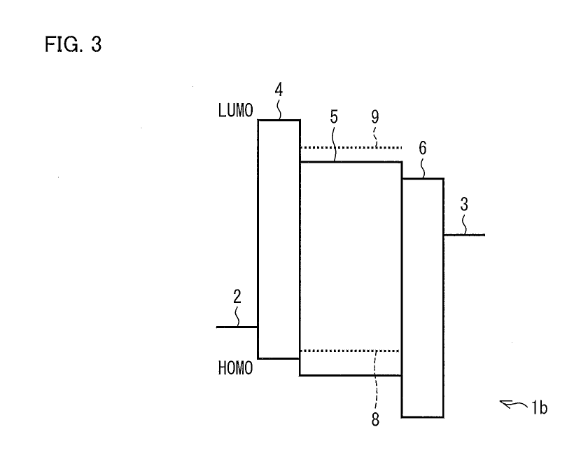

The following describes how the organic layer of the organic EL element 1 is configured, with reference to FIGS. 1 through 3. FIG. 1 is an energy diagram illustrating layers constituting the organic EL element 1. FIG. 2 is an energy diagram illustrating layers constituting an organic EL element 1a. FIG. 3 is an energy diagram illustrating layers constituting an organic EL element 1b.

As early described, the organic layer of the organic EL element 1 is made up of the hole transport layer 4, the emission layer 5, and the electron transport layer 6, which are stacked in this order. The emission layer 5 is doped with a phosphorescent material (organic light emitting material). A positive hole, which has been injected from the anode 2, is transported to the emission layer 5 via the hole transport layer 3. On the other hand, an electron, which has been injected from the cathode 3, is transported to the emission layer 5 via the electron transport layer 6. In the emission layer 5, the positive hole, which has been transported via the hole transport layer 4, recombines with the electron, which has been transported via the electron transport layer 6. This causes the organic EL element 1 to emit light.

The organic EL element 1 of the present embodiment is configured such that the positive holes and the electrons are certainly transported to the emission layer 5. Specifically, the emission layer 5 is made of a host material which has (i) a HOMO shallower than a HOMO 8 of the phosphorescent material and (ii) a LUMO deeper than a LUMO 9 of the phosphorescent material (see FIG. 1). This allows prevention of a positive hole, which has been transported via the hole transport layer 4, from being moved to the electron transport layer 6. Similarly, it is possible to prevent an electron, which has been transported via the electron transport layer 6, from being moved to the hole transport layer 4. This causes the positive hole and the electron to be confined within the emission layer 5, and therefore a positive hole becomes more likely to recombine with an electron in the emission layer 5. As such, it becomes possible to reduce a voltage necessary for driving the organic EL element 1. Since positive holes become more likely to recombine with electrons in the emission layer 5, internal quantum yield rate is improved. This allows an improvement in luminous efficiency.

Note that it is preferable that a difference is not more than 0.5 eV between the HOMO of the host material of the emission layer 5 and the HOMO 8 of the phosphorescent material. This is caused by the fact that the positive holes and the electrons are transported by the hopping conduction in the organic EL element 1. During the hopping conduction, a mobility of the positive hole decreases in accordance with exp(−ΔE/RT), where “ΔE” is a difference between an energy level at which the positive holes are trapped and an energy level at which the positive holes hop, “R” is a gas constant, and “T” is an absolute temperature [K]. Because of this, in a case where a difference is more than 0.5 eV between the HOMO of the host material and the HOMO 8, the positive holes become less likely to be thermally excited in the emission layer 5. The value of 0.5 eV can be explained by using the Arrhenius' equation. Since an electric field is applied, the positive holes are hardly moved from the host material to an anode side material. That is, the positive holes are moved from the host material to the phosphorescent material, in a case where a difference is not more than 0.5 eV between the HOMO of the host material and the HOMO 8.

Since a difference is more than 0 eV between the HOMO of the host material and the HOMO 8, it is possible to reduce a difference between the HOMO of and the LUMO of the host material itself. This allows a reduction in voltage required for operating a display device itself.

Similarly, it is preferable that a difference is not more than 0.5 eV between the LUMO of the host material of the emission layer 5 and the LUMO 9 of the phosphorescent material. In this case, since an electric field is applied, the positive holes are hardly moved from the host material to a cathode side material. This is similar to the case of the energy difference between the HOMO of the host material and the HOMO 8 of the phosphorescent material. Namely, since the difference is not more than 0.5 eV between the LUMO of the host material and the LUMO 9, the electrons are moved from the host material to the phosphorescent material.

Since a difference is more than 0 eV between the LUMO of the host material and the LUMO 9, it is possible to reduce a difference between the HOMO of and the LUMO of the host material itself. This allows a reduction in voltage required for operating a display device itself.

Note, however, that both the conditions (on the HOMOs and the LUMOs) are not necessarily satisfied. At least one of the two conditions can be satisfied. For example, an organic EL element 1a can be employed which includes an emission layer 5 made of a host material which has (i) a HOMO shallower than a HOMO 8 of a phosphorescent material and (ii) a LUMO shallower than a LUMO 9 of the phosphorescent material (see FIG. 2). Alternatively, an organic EL element 1b can be employed which includes an emission layer 5 made of a host material which has (i) a LUMO deeper than a LUMO 9 of a phosphorescent material and (ii) a HOMO deeper than a HOMO 8 of the phosphorescent material (see FIG. 3). It is possible to sufficiently increase probability of positive holes recombining with electrons, provided that any one of the conditions is satisfied.

Note that it is preferable that the hole transport layer 4 is made of a hole-transporting material having a LUMO which (i) is shallower than that of the host material of the emission layer 5 and (ii) is shallower than the LUMO 9 of the phosphorescent material. With the configuration, it is possible to prevent an electron, which has been transported to the emission layer 5, from being moved to the hole transport layer 4. It is preferable that (i) a difference is more than 0.5 eV between a LUMO of the hole transport layer 4 and a LUMO 9 of the phosphorescent material and (ii) a difference is more than 0.5 eV between the LUMO of the hole transport layer 4 and a LUMO of the host material of the emission layer 5. With the configuration, since the difference is more than 0.5 eV between the LUMO of the hole transport layer 4 and the LUMO 9 of the phosphorescent material, it is possible to hold down the probability that an electron can be thermally excited at a boundary between the emission layer 5 and the hole transport layer 4. The same applies to the case where the difference is more than 0.5 eV between the LUMO of the hole transport layer 4 and the LUMO of the host material of the emission layer 5. It is therefore possible to prevent an electron from being moved to a hole transport layer 4 side.

Similarly, it is preferable that the electron transport layer 6 is made of an electron-transporting material having a HOMO which (i) is deeper than that of the host material of the emission layer 5 and (ii) is deeper than the HOMO 8 of the phosphorescent material. With the configuration, it is possible to prevent a positive hole, which has been transported to the emission layer 5, from being moved to the electron transport layer 6. It is preferable that (i) a difference is more than 0.5 eV between a HOMO of the electron transport layer 6 and a HOMO 8 of the phosphorescent material and (ii) a difference is more than 0.5 eV between the HOMO of the electron transport layer 6 and a HOMO of the host material for the emission layer 5. With the configuration, since the difference is more than 0.5 eV between the HOMO of the electron transport layer 6 and the HOMO 8 of the phosphorescent material, it is possible to hold down the probability that a positive hole can be thermally excited at a boundary between the emission layer 5 and the electron transport layer 6. The same applies to the case where the difference is more than 0.5 eV between the HOMO of the electron transport layer 6 and the HOMO of the host material for the emission layer 5. It is therefore possible to prevent a positive hole from being moved to an electron transport layer 6 side.

The above description has discussed preferable materials for respective of the hole transport layer 4 and the electron transport layer 6. Note, however, that it is not necessarily required to employ materials for respective of the hole transport layer 4 and the electron transport layer 6 which materials meet the above respective conditions. For example, it is possible to appropriately determine which one of the hole transport layer 4 and the electron transport layer 6 should prevent a carrier (positive hole or electron) from being moved, in accordance with whether positive holes recombine with electrons (i.e., emissions occur) predominantly on a hole transport layer 4 side or on an electron transport layer 6 side. It is possible to sufficiently bring about the effect, even in the case where only one of the hole transport layer 4 and the electron transport layer 6 is made of the material which can block the movement of the carriers.

In order to confine excitation energy within the phosphorescent material, it is preferable that the hole transport layer 4 is made of a material which has an excited triplet energy level (T₁) higher than that of the phosphorescent material, with which the emission layer 5 is doped. Similarly, it is preferable that the electron transport layer 6 is made of a material which has an excited triplet energy level higher than that of the phosphorescent material. Note that, even in a case where each of the hole transport layer 4 and the electron transport layer 6 is made of a material which has an excited triplet energy level lower than that of the phosphorescent material, the excitation energy is hardly moved from the phosphorescent material, provided that a difference is about 0.1 eV between (i) the excited triplet energy level of each of the material of the hole transport layer 4 and the material of the electron transport layer 6 and (ii) the excited triplet energy level of the phosphorescent material. This is because in a case where such a difference is not more than 0.1 eV, a moving process of the excitation energy occurs in an electron-exchanging manner. As such, the phosphorescent material can be returned to its original state by electron exchange between the phosphorescent material and its other peripheral material (such as the hole-transporting material, the electron-transporting material, and/or the host material). Each of the hole transport layer 4 and the electron transport layer 6 can therefore be made of a material which has an excited triplet energy level lower, by approximately 0.1 eV, than that of the phosphorescent material.

According to the organic electroluminescence element of the present invention, the hole transport layer is made of a material having an excited triplet energy level (i) which is higher than that of the organic light emitting material or (ii) which is lower, by 0.1 eV or less, than that of the organic light emitting material.

According to the organic electroluminescence element of the present invention, the electron transport layer is made of a material having an excited triplet energy level (i) which is higher than that of the organic light emitting material or (ii) which is lower, by 0.1 eV or less, than that of the organic light emitting material.

According to the organic EL element 1 of the present embodiment, the host material of the emission layer 5 is determined by taking into consideration the HOMO 8 and the LUMO 9 of the phosphorescent material. This allows prevention of a positive hole, which has been transported to the emission layer 5, from being moved to the electron transport layer 6. Similarly, it is possible to prevent an electron, which has been transported to the emission layer 5, from being moved to the hole transport layer 4. This causes the positive hole and the electron to be confined within the emission layer 5, and therefore a positive hole becomes more likely to recombine with an electron. As such, the probability that the positive hole can recombine with the electron is increased in the organic EL element 1 of the present embodiment. This allows a reduction in voltage necessary for driving the organic EL element 1. Since positive holes become more likely to recombine with electrons in the emission layer 5, internal quantum yield rate is improved. This allows an improvement in luminous efficiency.

A conventional organic EL element, in which a blue phosphorescent material is used, has a problem that luminous efficiency is low, in spite of a high driving voltage being required. On the other hand, according to the present embodiment, a positive hole and an electron can be confined within the emission layer 5, even in a case where a blue phosphorescent material is used. In other words, according to the present embodiment, it is possible to increase the probability of positive holes recombining with electrons, and therefore internal quantum yield rate of the organic EL element 1 can be improved. This allows an improvement in luminous efficiency.

(Substrate of Organic EL Element 1)

The following describes constituent members of the organic EL element 1. As early described, the organic EL element 1 includes the anode 2 and the cathode 3 which are provided above the substrate (not illustrated). The organic EL element 1 further includes the organic layer provided between the anode 2 and the cathode 3. The organic layer is made up of the hole transport layer 4, the emission layer 5, and the electron transport layer 6.

The following description will first discuss the substrate. The substrate, which is included in the organic EL element 1, is not limited to a particular one, provided that it has an insulating property. A material, which can be used as the substrate of the organic EL element 1, is not limited to a particular one. It is therefore possible to use, for example, a known insulating substrate material.

Examples of such an insulating substrate material encompass (i) an inorganic material substrate made of a material such as glass or quartz and (ii) a plastic substrate made of a material such as polyethylene terephthalate or polyimide resin. Alternatively, it is possible to use a substrate which is prepared by coating a metal substrate, which is made of a metal such as aluminum (Al) or iron (Fe), with an insulator made of a material such as silicon oxide or an organic insulating material. Alternatively, it is possible to use a substrate, which is prepared by carrying out an insulating treatment by use of a method such as an anodic oxidation with respect to a surface of a metal substrate made of a metal such as aluminum (Al).

Note that, in a case where light, which has been emitted from the emission layer 5 of the organic EL element 1, is emitted from an opposite side of the substrate, i.e., in a case where the organic EL element 1 is of a top-emission type, it is preferable that the substrate is made of a material which has no light-transmitting property. For example, a semiconductor substrate such as a silicon wafer can be used as the substrate. In contrast, in a case where light, which has been emitted from the emission layer 5 of the organic EL element 1, is emitted from a substrate side, i.e., in a case where the organic EL element 1 is of a bottom-emission type, it is preferable that the substrate is made of a material which has a light-transmitting property. For example, a substrate such as a glass substrate or a plastic substrate can be used as the substrate.

(Electrodes of Organic EL Element 1)

The following description will discuss the electrodes. The electrodes included in the organic EL element 1 are not limited in particular, provided that they serve as a pair like the anode 2 and the cathode. Each of the electrodes can have a single layer structure in which the single layer is made from a single electrode material. Alternatively, each of the electrodes can have a multilayer structure in which a plurality of layers are made from respective electrode materials. The electrode materials, which can be used as materials for the respective electrodes of the organic EL element 1, are not limited to particular ones, and therefore each of the electrodes can be made from, for example, a known electrode material(s).

The anode 2 can be made of (i) a metal such as gold (Au), platinum (Pt), or nickel (Ni) or (ii) a transparent electrode material such as indium tin oxide (ITO), tin oxide (SnO₂), or indium zinc oxide (IZO).

On the other hand, the cathode 3 can be made of (i) a metal such as lithium (Li), calcium (Ca), cerium (Ce), barium (Ba), or aluminum (Al) or (ii) an alloy, including at least one of the metals, such as a magnesium-silver (Mg—Ag) alloy or an Li—Al alloy.

Note that light, which has been emitted from the emission layer 5 of the organic EL element 1, needs to be emitted from an anode 2 side or from a cathode 3 side. In this case, it is preferable that (i) one of the anode 2 and the cathode 3 is made of an electrode material which passes the light through and (ii) the other is made of an electrode material which blocks the light. Examples of the electrode material, which blocks the light, encompass (i) a black electrode material such as tantalum or carbon and (ii) a reflective metal electrode material such as Al, Ag, Au, an Al—Li alloy, an aluminum-neodymium (Al—Nd) alloy, or an aluminum-silicon (Al—Si) alloy.

(Organic Layer of Organic EL Element 1)

The following description will discuss the organic layer. The organic layer is made up of the hole transport layer 4, the emission layer 5, and the electron transport layer 6.

The following description will first discuss the emission layer 5. As early described, the emission layer is doped with a phosphorescent material. The phosphorescent material, with which the emission layer 5 can be doped, is not limited to a particular one. For example, a known phosphorescent material can be used.

A blue phosphorescent material can be used as the phosphorescent material. Examples of such a blue phosphorescent material encompass (i) Ir-complexes such as iridium(III)bis(4′,6′-difluorophenylpyridinato)tetrakis(1-pyrazolyl)borate (FIr6) (HOMO=6.1 eV, LUMO=3.1 eV, and excited triplet energy level=2.71 eV), iridium(III)bis[4,6-(di-fluorophenyl)-pyridinato-N, C2′]picolinate (FIrpic), iridium(III)tris[N-(4′-cyanophenyl)-N′-methylimidazole-2-ylidene-C2,C2′](Ir(cn-pmic)₃), tris((3,5-difluoro-4-cyanophenyl)pyridine)iridium (FCNIr), and Ir(cnbic)₃, and (ii) complexes of heavy-atom metals such as platinum (Pt), rethenium (Re), ruthenium (Ru), copper (Cu), and osmium (Os).

As early described, the emission layer 5 is made of the host material which has the HOMO shallower than the HOMO 8 of the phosphorescent material, with which the emission layer 5 is doped, so that a positive hole, which has been transported via the hole transport layer 4, is prevented from being moved to the electron transport layer 6. Moreover, the host material of the emission layer 5 has the LUMO deeper than the LUMO 9 of the phosphorescent material so that an electron, which has been transported via the electron transport layer 6, is prevented from being moved to the hole transport layer 4. Examples of the host material encompass adamantane carbazole (Ad-Cz) (HOMO=5.8 eV, LUMO=2.6 eV, and excited triplet energy level=2.88 eV) and 4,4′,4″-tris(carbazole-9-yl)triphenylamine (TCTA) (HOMO=5.8 eV, LUMO=2.7 eV, and excited triplet energy level=2.85 eV). Note, however, that the host material is not limited to these. The host material of the organic EL element 1 can be selected as appropriate so that the foregoing conditions are satisfied, after a phosphorescent material of the organic EL element 1 has been determined. Therefore, the host material is not limited to the materials listed above, provided that the host material satisfies the foregoing conditions.

It is preferable that the emission layer 5 is made of a host material which has an excited triplet energy level higher than that of the phosphorescent material, with which the emission layer 5 is doped, so that excitation energy can be confined within the phosphorescent material. Note that, even in a case where the host material has an excited triplet energy level lower than that of the phosphorescent material, the excitation energy is hardly moved from the phosphorescent material, provided that a difference is about 0.1 eV between the excited triplet energy level of the host material and the excited triplet energy level of the phosphorescent material. It is therefore possible to employ a host material which has an excited triplet energy level lower, by approximately 0.1 eV, than that of the phosphorescent material.

As early described, the host material used in the organic EL element 1 does not need to satisfy both the conditions that (i) the host material has a HOMO higher than the HOMO 8 of the phosphorescent material with which the emission layer 5 is doped and (ii) the host material has a LUMO lower than the LUMO 9 of the phosphorescent material, provided that at least one of the conditions is satisfied. It is therefore possible to employ the host material, which is used in the organic EL element 1a (see FIG. 2), having (i) a HOMO shallower than the HOMO 8 of the phosphorescent material with which the emission layer 5 is doped and (ii) a LUMO shallower than the LUMO 9 of the phosphorescent material. In this case, it is preferable that the host material of the emission layer 5 has HOMO and LUMO which are similar to respective HOMO and LUMO of a host material used as a conventional hole-transporting material. This allows electrons to be confined within the emission layer 5. Moreover, the host material of the emission layer 5 preferably has an excited triplet energy level higher than that of the phosphorescent material, with which the emission layer 5 is doped. This allows excitation energy to be confined within the phosphorescent material. Note, however, that, even in a case where the host material has an excited triplet energy level lower than that of the phosphorescent material, the excitation energy is hardly moved from the phosphorescent material, provided that a difference is about 0.1 eV between the excited triplet energy level of the host material and the excited triplet energy level of the phosphorescent material. It is therefore possible to employ a host material which has an excited triplet energy level lower, by about 0.1 eV, than that of the phosphorescent material.

Examples of the host material of the emission layer 5 of the organic EL element 1a, encompass CzSi, 1,3-bis(carbazole-9-yl)benzene (mCP) (HOMO=5.9 eV, LUMO=2.4 eV, and excited triplet energy level=2.9 eV), and Ad-Cz. Note, however, that the host material is not limited to these. The host material of the organic EL element 1a can be selected as appropriate so that the foregoing conditions are satisfied, after a phosphorescent material of the organic EL element 1a has been determined. Therefore, the host material of the organic EL element 1a is not limited to the materials listed above, provided that the host material satisfies the foregoing conditions.

Alternatively, it is possible to employ a host material, which is used in the organic EL element 1b (see FIG. 3), having (i) a LUMO deeper than the LUMO 9 of the phosphorescent material with which the emission layer 5 is doped and (ii) a HOMO deeper than the HOMO 8 of the phosphorescent material. In this case, it is preferable that the host material of the emission layer 5 has HOMO and LUMO which are similar to respective HOMO and LUMO of a host material used as a conventional electron-transporting material. This allows positive holes to be confined within the emission layer 5. Moreover, the host material of the emission layer 5 preferably has an excited triplet energy level higher than the excited triplet energy level of the phosphorescent material, with which the emission layer 5 is doped. This allows excitation energy to be confined within the phosphorescent material. Note, however, that, even in a case where the host material has an excited triplet energy level lower than the excited triplet energy level of the phosphorescent material, the excitation energy is hardly moved from the phosphorescent material, provided that a difference is about 0.1 eV between the excited triplet energy levels. It is therefore possible to employ a host material which has an excited triplet energy level lower, by about 0.1 eV, than that of the phosphorescent material.

Examples of the host material, which constitutes the emission layer 5 of the organic EL element 1b, encompass tris(2,4,6-trimethyl-3-(pyridine-3-yl)phenyl)borane (3TPYMB) (HOMO=6.8 eV, LUMO=3.3 eV, and excited triplet energy level=2.98 eV) and 1,3,5-tri(m-pyridi-3-yl-phenyl)benzene (TmTyPB) (HOMO=6.68 eV, LUMO=2.73 eV, and excited triplet energy level=2.78 eV). Note, however, that the host material is not limited to these. The host material of the organic EL element 1b, can be selected as appropriate so that the foregoing conditions are satisfied, after a phosphorescent material of the organic EL element 1b has been determined. Therefore, the host material, which is used in the organic EL element 1b, is not limited to the materials listed above, provided that the host material satisfies the foregoing conditions.

Then, the following description will discuss the hole transport layer 4. A hole-transporting material, which can be used as a material of the hole transport layer 4, is not limited to a particular one. For example, a known hole-transporting material can be used. Examples of such a hole-transporting material encompass di-[4-(N,N-ditolyl-amino)-phenyl]cyclohexane (TAPC) (HOMO=5.5 eV, LUMO=1.8 eV, and excited triplet energy level=2.87 eV), 9,10-diphenylanthracene-2-sulfonate (DPAS), N,N′-diphenyl-N,N′-(4-(di(3-tolyl)amino)phenyl)-1,1′-biphenyl-4,4′-diamine (DNTPD), iridium(III)tris[N,N′-diphenylbenzimidazol-2-ylidene-C2,C2′](Ir(dpbic)₃), 4,4′,4″-tris-(N-carbazolyl)-triphenylamine (TCTA), 2,2-bis(p-trimellitoxyphenyl)propanoic acid anhydride (BTPD), bis[4-(p,p-ditolylamino)phenyl]diphenylsilane (DTASi), mCP, and Ad-Cz. The hole transport layer 4 of the present embodiment can be made of a material which is either identical with or different from the host material of the emission layer 5. Note, however, that, in a case where the hole transport layer 4 is made of a material which is identical with the host material of the emission layer 5, the host material needs to have a HOMO which is shallower than the HOMO 8 of the phosphorescent material with which the emission layer 5 is doped. This allows a reduction in the amount of materials of the organic EL element 1, and therefore manufacturing cost can be reduced.

The hole transport layer 4 can be doped with a p-dopant such as tetrafluorotetracyanoquinodimethan (TCNQF4) so that hole transportation in the hole transport layer 4 is facilitated. This allows a further reduction in voltage necessary for driving the organic EL element 1.

As above described, the hole-transporting material of the hole transport layer 4 preferably has an excited triplet energy level which is higher than that of the phosphorescent material with which the emission layer 5 is doped. In a case where the hole transport layer 4 is made of a hole-transporting material having an excited triplet energy level lower than that of the phosphorescent material, it is preferable that the organic EL element 1 is configured such that excitation energy can be confined within the phosphorescent material. Specifically, a layer, which is made of only a host material, can be provided between the hole transport layer 4 and the emission layer 5. The layer serves as an electron-blocking layer which prevents an energy deactivation from being caused by an exciplex in an interface between the emission layer 5 and the hole transport layer 4. That is, the layer can prevent energy loss, i.e., the energy from being moved from the emission layer 5 to the hole transport layer 4.

The following description will discuss the electron transport layer 6. An electron-transporting material of the electron transport layer 6 is not limited to a particular one. For example, a known electron-transporting material can be used. Examples of such an electron-transporting material encompass 2,9-dimethyl-4,7-diphenyl-1,10-phenanthroline (BCP), 1,3,5-tris(N-phenylbenzimidazole-2-yl)benzene (TPBI), 3-phenyl-4(1′-naphthyl)-5-phenyl-1,2,4-triazole (TAZ), 4,7-diphenyl-1,10-phenanthroline (Bphen), Ad-Cz, dipalmitoylphosphatidylserine (DPPS), 1,3,5-tri(m-pyrido-3-yl-phenyl)benzene (TmPyPB), 1,3,5-tri(p-pyrido-3-yl-phenyl)benzene (TpPyPB), 3TPYMB, and TmTyPB. The electron transport layer 6 of the present embodiment can be made of a material which is either identical with or different from the host material of the emission layer 5. Note, however, that, in a case where the electron transport layer 6 is made of a material which is identical with the host material of the emission layer 5, the host material needs to have a LUMO which is deeper than the LUMO 9 of the phosphorescent material with which the emission layer 5 is doped. This allows a reduction in the amount of materials of the organic EL element 1, and therefore manufacturing cost can be reduced.

The electron transport layer 6 can be doped with an n-dopant such as cesium carbonate (Cs₂CO₃) so that electron transportation in the electron transport layer 6 is facilitated. This allows a further reduction in voltage necessary for driving the organic EL element 1.

As early described, the electron-transporting material of the electron transport layer 6 preferably has an excited triplet energy level which is higher than that of the phosphorescent material with which the emission layer 5 is doped. In a case where the electron transport layer 6 is made of an electron-transporting material having an excited triplet energy level lower than that of the phosphorescent material, it is preferable that the organic EL element 1 is configured such that excitation energy can be confined within the phosphorescent material. Specifically, a layer, which is made of only a host material, can be provided between the electron transport layer 6 and the emission layer 5. The layer serves as a hole-blocking layer which prevents an energy deactivation from being caused by an exciplex in an interface between the emission layer 5 and the electron transport layer 6. That is, the layer can prevent energy loss, i.e., the energy from being moved from the emission layer 5 to the electron transport layer 6.

(Method for Manufacturing Organic EL Element 1)

The following description will briefly discuss how the organic EL element 1 is manufactured. As early described, an organic EL element has a transistor which serves as a switching element. Note, however, that the present embodiment will not refer to steps of preparing such a transistor.

The following description will discuss how to form an anode 2, an organic layer, and a cathode 3, on a substrate on which a plurality of transistors have been provided in an island-shaped manner. First, anodes 2 are patterned above the respective plurality of transistors (step of forming an anode). Then, an organic layer is formed by stacking layers over the anodes 2. Note that an organic insulating film (not illustrated) can be formed on the periphery of the anodes 2 so as to secure insulation around the respective anodes 2. It is preferable that the organic insulating film is made of a material such as a polyimide resin material. However, the material used to constitute the organic insulating film is not limited to this. Instead of them, a known organic insulating material, for example, can be used.

Then, a hole transport layer 4 is formed (step of forming a hole transport layer). The hole transport layer 4 is formed by depositing a hole-transporting material over the anodes 2. In this case, it is preferable that the hole transport layer 4 is deposited to have a thickness of approximately 50 nm. The hole transport layer 4 is thus formed.

Subsequently, an emission layer 5 is formed. Specifically, the emission layer 5 is formed by concurrently depositing a host material and a phosphorescent material on the hole transport layer 4 (step of forming an emission layer). In this case, it is preferable that the host material is doped with the phosphorescent material so that the phosphorescent material accounts for approximately 7.5% of the emission layer 5. The emission layer 5 is thus formed. Note that it is preferable for the emission layer 5 to have a thickness of approximately 30 nm.

Then, an electron transport layer 6 is formed (step of forming an electron transport layer). The electron transport layer 6 is formed by depositing an electron-transporting material on the emission layer 5. In this case, it is preferable that the electron transport layer 6 has a thickness of approximately 30 nm. The electron transport layer 6 is thus formed.

Lastly, cathodes are formed (step of forming a cathode). The cathodes 3 are patterned on the electron transport layer 6, and an organic EL element 1 is thus prepared. This is how the organic EL element 1 of the present embodiment is prepared. Note that the organic EL element 1 of the present embodiment only needs to include at least the three layers, i.e., the hole transport layer 4, the emission layer 5, and the electron transport layer 6. This allows the organic EL element 1 to have a simple layered structure. It is therefore possible to manufacture the organic EL element 1 not by a complex manufacturing method but by an easy manufacturing method. Since the organic EL element 1 has the simple layered structure, it is easy to dope the hole transport layer 4, the electron transport layer 6, and the like, with dopants.

The present invention is not limited to the embodiments, but can be altered by a skilled person in the art within the scope of the claims. An embodiment derived from a proper combination of technical means disclosed in respective different embodiments is also encompassed in the technical scope of the present invention.

For example, another organic light emitting material, such as a phosphorescent material having a color other than blue or a fluorescent material, can be used in the present embodiment instead of the blue phosphorescent material. It is possible to further reduce a voltage necessary for driving the organic EL element 1, even in a case where the organic EL element 1 of the present embodiment is made of an organic light emitting material other than the blue phosphorescent material.

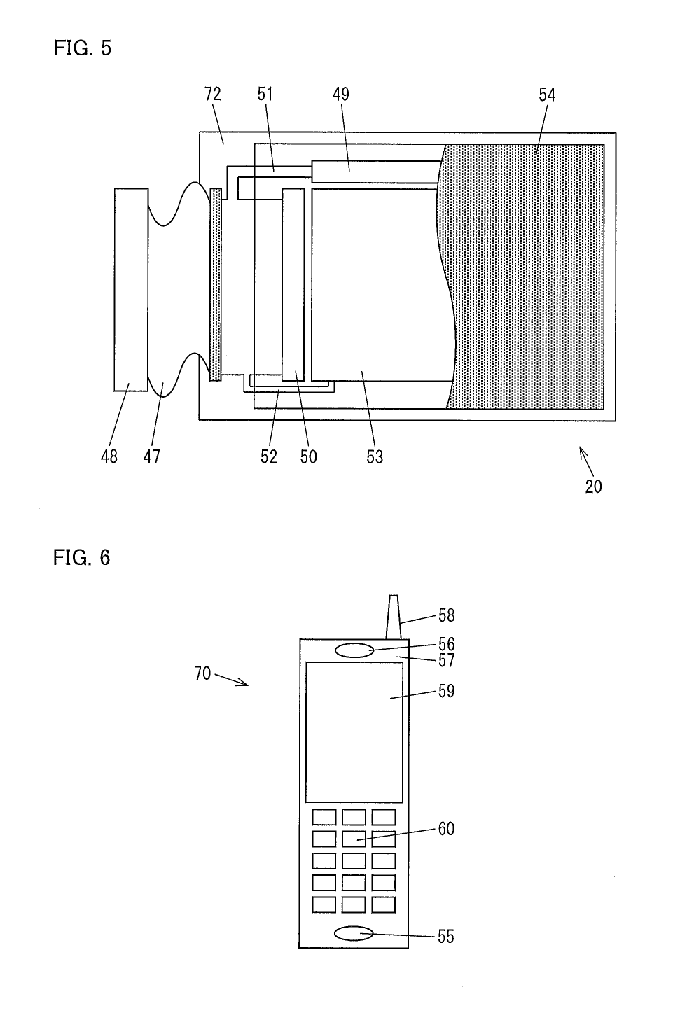

It is possible to provide an organic EL display device including display means having an organic EL element 1 of the present embodiment. The following describes a concrete example of such an organic EL display device with reference to FIG. 5. FIG. 5 is a view schematically illustrating an organic EL display device 20 which includes the organic EL element 1.

The organic EL display device 20, which includes the organic EL element 1, further includes (i) a substrate 72 on which a pixel section 53, a gate signal side driving circuit 50, a data signal side driving circuit 49, a wire 51, a current supply line 52, and a sealing substrate 54 are provided, (ii) an FPC (Flexible Printed Circuit) 47, and (iii) an external driving circuit 48 (see FIG. 5).

The external driving circuit 48 controls (i) the gate signal side driving circuit 50 to sequentially select scanning lines in the pixel section 53 and (ii) the data signal side driving circuit 49 to write pieces of pixel data into respective pixels which are provided along a selected one of the scanning lines. That is, the gate signal side driving circuit 50 sequentially drives the scanning lines and the data signal side driving circuit 49 supplies pieces of pixel data to the respective data lines. Each pixel, which is located at an intersection of a corresponding one of the scanning lines and a corresponding one of the data lines, is driven when (i) the gate signal side driving circuit 50 drives the corresponding one of the scanning lines and (ii) the data signal side driving circuit 49 supplies a piece of pixel data to the corresponding one of the data lines.

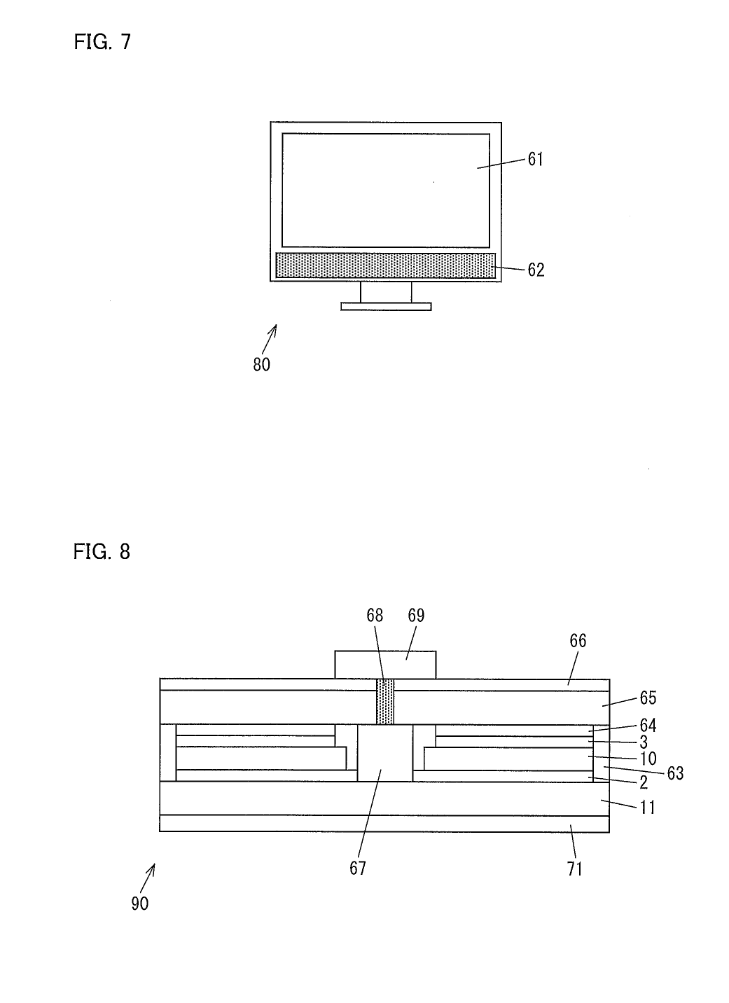

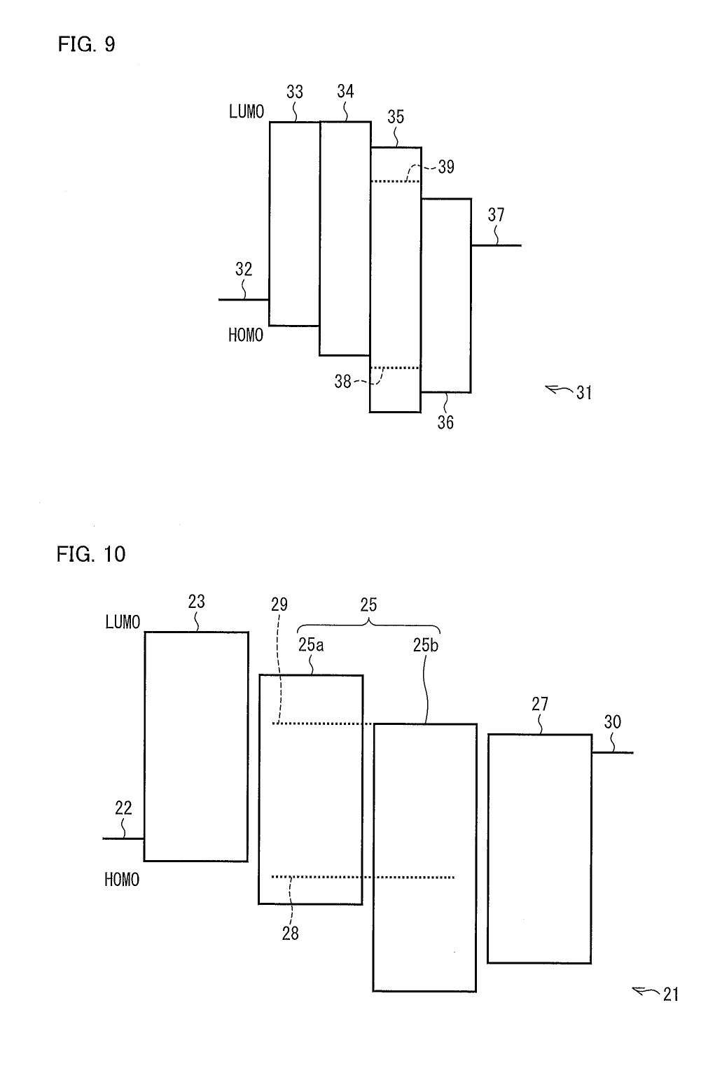

It is also possible to provide an electronic device including the above organic EL display device. Concrete examples are illustrated in FIGS. 6 and 7. FIG. 6 is a view schematically illustrating a mobile phone 70 which includes the organic EL display device. FIG. 7 is a view schematically illustrating a television receiver 80 which includes the organic EL display device.

The organic EL display device, which includes the organic EL element 1 of the present embodiment, can be employed as a display section 59 of the mobile phone 70 (see FIG. 6). The mobile phone 70 further includes a voice input section 55, a voice output section 56, a main body 57, an antenna 58, and operation switches 60 (see FIG. 6). These constituent members have functions similar to those of a conventional mobile phone, and therefore descriptions of the constituent members are omitted here. Moreover, detailed descriptions of how the mobile phone 70 is configured are omitted here.

The organic EL display device, which includes the organic EL element 1 of the present embodiment, can be employed as a display section 61 of the television receiver 80 (see FIG. 7). A reference numeral 62 indicates a speaker. Detailed descriptions of how the television receiver 80 is configured are omitted here. This is because the television receiver 80 has a configuration similar to a conventional television receiver, except that the organic EL display device of the present embodiment is employed as the display section 61 of the television receiver 80.

It is possible to provide an organic EL display device with high luminous efficiency, by thus including the organic EL element 1 of the present embodiment, and such an organic EL display device can be employed as a display section included in various kinds of electronic devices.

The descriptions have thus discussed the organic EL display device, including the display means having the organic EL element 1 of the present embodiment. Note, however, that the organic EL element 1 can be used also as a light source of an illumination device. The following description will discuss a concrete example of such an illumination device with reference to FIG. 8. FIG. 8 is a view schematically illustrating an illumination device 90 including the organic EL element 1.

The illumination device 90, which includes the organic EL element 1, further includes an optical film 71, a substrate 11, an anode 2, an organic EL layer 10, a cathode 3, a thermal diffusion sheet 64, a sealing substrate 65, a sealing resin 63, a heat radiation member 66, a driving circuit 67, a wire 68, and a hook 69 for suspending the illumination device 90 from a ceiling (see FIG. 8).

It is possible to provide an illumination device with high luminous efficiency, by thus including the organic EL element 1 of the present embodiment.

### [Recapitulation of Embodiment]

According to the organic electroluminescence element of the present invention, a material of the electron transport layer, the host material, and the organic light emitting material have respective highest occupied molecular orbitals (HOMOs) which satisfy the following relational expressions (3) and (4):

0.5 eV<(|HOMO of material of electron transport layer|−|HOMO of host material|) (3)

0.5 eV<(|HOMO of material of electron transport layer|−|HOMO of organic light emitting material|) (4)

According to the configuration, each of the host material and the organic light emitting material has the highest occupied molecular orbital which is deeper, by 0.5 eV, than that of the material of the electron transport layer [0.5 eV<(|HOMO of material of electron transport layer|−|HOMO of host material|) and 0.5 eV<(|HOMO of material of electron transport layer|−|HOMO of organic light emitting material|)]. This allows prevention of a positive hole, which has been transported via the hole transport layer, from being moved to the electron transport layer. In a case where the material for the electron transport layer has a hole mobility which is 1.0×10⁻⁵ cm²/Vs or less, no positive hole can enter the electron transport layer, and therefore light will be emitted from a side of the emission layer which side faces the electron transport layer. This causes a positive hole to be confined within the emission layer, and therefore the positive hole becomes more likely to recombine with the electron. As such, it becomes possible to reduce a voltage necessary for driving the organic electroluminescence element (organic EL element). Since positive holes become more likely to recombine with electrons, internal quantum yield rate can be improved. This allows an improvement in luminous efficiency.

According to the organic electroluminescence element of the present invention, the material of the electron transport layer has an excited triplet energy level (i) which is higher than that of the organic light emitting material or (ii) which is lower, by 0.1 eV or less, than that of the organic light emitting material.

With the configuration, it is possible to confine excitation energy within the organic light emitting material contained in the emission layer. This allows prevention of the excitation energy from being moved from the organic light emitting material.

According to the organic electroluminescence element of the present invention, the material of the electron transport layer has a hole mobility (μH) which satisfies the following relational expression (5):

μ_{H}≦1.0×10⁻⁵ cm²/Vs (5)

According to the organic electroluminescence element of the present invention, a material of the hole transport layer, the host material, and the organic light emitting material have respective lowest unoccupied molecular orbitals (LUMOs) which satisfy the following relational expressions (8) and (9):

0.5 eV<(|LUMO of host material|−|LUMO of material of hole transport layer|) (8)

0.5 eV<(|LUMO of organic light emitting material|−|LUMO of material of hole transport layer|) (9)

With the configuration, it is possible to prevent an electron, which has been transported to the emission layer, from being moved to the hole transport layer. In a case where the hole transporting material has an electron mobility which is 1.0×10⁻⁵ cm²/Vs or less, no electron can enter the hole transport layer, and therefore light will be emitted from a side of the emission layer which side faces the hole transport layer.

According to the organic electroluminescence element of the present invention, the material of the hole transport layer has an excited triplet energy level (i) which is higher than that of the organic light emitting material or (ii) which is lower, by 0.1 eV or less, than that of the organic light emitting material.

With the configuration, it is possible to confine excitation energy within the organic light emitting material contained in the emission layer. This allows prevention of the excitation energy from being moved from the organic light emitting material.

According to the organic electroluminescence element of the present invention, the material of the hole transport layer has an electron mobility (μ_{E}) which satisfies the following relational expression (10):

μ_{E}≦1.0×10⁻⁵ cm²/Vs (10)

The organic electroluminescence element of the present invention further includes a layer (i) which is provided between the hole transport layer and the emission layer and (ii) which is not doped with an organic light emitting material.

The organic electroluminescence element of the present invention further includes a layer (i) which is provided between the electron transport layer and the emission layer and (ii) which is not doped with an organic light emitting material.

According to the configuration, the layer, (i) which is provided between the emission layer and the hole transport layer and (ii) which is not doped with an organic light emitting material, serves as an electron-blocking layer. This allows prevention of an energy deactivation from being caused by an exciplex in an interface between the emission layer and the hole transport layer. That is, the layer prevents energy from being moved from the emission layer to the hole transport layer. Similarly, the layer, (i) which is provided between the emission layer and the electron transport layer and (ii) which is not doped with an organic light emitting material, can prevent energy from being moved from the emission layer to the electron transport layer.

According to the organic electroluminescence element of the present invention, the hole transport layer is doped with a dopant which facilitates transportation of a positive hole.

According to the organic electroluminescence element of the present invention, the electron transport layer is doped with a dopant which facilitates transportation of an electron.

With the configurations, it is possible to facilitate (i) transportation of positive holes, which have been injected via the anode, to the emission layer and (ii) injection of the electron, which has been injected via the cathode, to the emission layer. This allows positive holes and electrons to be sufficiently transported to the emission layer.

According to the organic electroluminescence element of the present invention, the hole transport layer is made of a material which is identical with the host material.

According to the organic electroluminescence element of the present invention, the electron transport layer is made of a material which is identical with the host material.

With the configuration, it is possible to reduce the number of kinds of materials used in the organic EL element, and therefore manufacturing cost can be reduced.

According to the organic electroluminescence element of the present invention, the organic light emitting material is a phosphorescent material.

With the configuration, it is possible to provide an organic EL element which has high luminous efficiency and long emission lifetime.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### EXAMPLES

The following description will further discuss, in detail with Examples, the present invention. Note that the present invention is not limited to the Examples without departing from the scope of the present invention.

### Example 1

A silicon semiconductor film was deposited on a glass substrate by plasma chemical vapor deposition (plasma CVD), and was then subjected to a crystallization treatment so that a polycrystalline semiconductor film was prepared. Subsequently, the polycrystalline silicon thin film was etched so that a plurality of island-shaped patterns of polycrystalline silicon thin film are formed. Then, silicon nitride (SiN) serving as a gate insulating film was formed over the plurality of island-shaped patterns. Next, a titanium layer, an aluminum layer, and a titanium layer are stacked on the gate insulating film, in this order, so as to form stacked films (titanium-aluminum-titanium (Ti—Al—Ti)) each serving as a gate electrode, and then the stacked films were etched to be patterned. Subsequently, a source electrode and a drain electrode, each having a stacked film structure of Ti—Al—Ti, were formed on a corresponding one of the gate electrodes. A plurality of thin film transistors were thus prepared.

An interlayer insulating film, which has through holes formed above the respective plurality of thin film transistors, was formed over the plurality of thin film transistors so as to achieve planarization. Then, indium tin oxide (ITO) electrodes serving as anodes were formed via the respective through holes. Then, a single-layered polyimide resin layer was patterned so as to surround the ITO electrodes. After that, the substrate, on which the ITO electrodes had been formed, was subjected to ultrasonic cleaning, and was then baked under reduced pressure at 200° C. for three hours.

Subsequently, a hole transport layer having a thickness of 50 nm was formed by depositing di-[4-(N,N-ditolyl-amino)-phenyl]cyclohexane (TAPC), at a deposition rate of 1 Å/sec, on the anodes by a vacuum deposition method.

Next, an emission layer having a thickness of 30 nm was formed on the hole transport layer by concurrently depositing (i) 9-(4-tert-butylphenyl)-3,6-bis(triphenylsilyl)-9H-carbazole (CzSi) and (ii) iridium(III)bis(4′,6′-difluorophenylpyridinato)tetrakis (1-pyrazolyl)borate (FIr6) on the hole transport layer by the vacuum deposition method. In this case, the CzSi was doped with the FIr6 so that the FIr6 accounts for approximately 7.5% of the emission layer.

Subsequently, an electron transport layer having a thickness of 30 nm was formed on the emission layer by depositing tris(2,4,6-trimethyl-3-(pyridine-3-yl)phenyl)borane (3TPYMB) by the vacuum deposition method.

Next, a cathode was formed by stacking lithium fluoride (LiF) and aluminum (Al), in this order, on the electron transport layer. Specifically, an LiF film having a thickness of 0.5 nm was formed by depositing LiF, at a deposition rate of 1 Å/sec, on the electron transport layer by the vacuum deposition method. After that, an Al film having a thickness of 100 nm was formed by depositing Al on the LiF film. An organic EL element was thus prepared.

A current efficiency and a life duration T₅₀ at 1000 cd/m² of the organic EL element thus prepared were measured. As a result, good values were obtained, i.e., the current efficiency was 10 cd/A and the life duration T₅₀ was 1000 h.

### Example 2

Note that steps, processed in Example 2 until before the step of forming an organic layer, are identical with those processed in Example 1. As such, descriptions of such steps are omitted here. The following description will therefore first discuss a step of forming a hole transport layer, and then discuss subsequent steps.

In this Example 2, a hole injection layer, having a thickness of 20 nm, was formed by depositing TAPC on anodes by the vacuum deposition method.

Then, a hole transport layer, having a thickness of 30 nm, was formed by depositing 1,3-bis(carbazole-9-yl)benzene (mCP) on the hole injection layer by the vacuum deposition method.

Subsequently, an emission layer, having a thickness of 30 nm, was formed by concurrently depositing tris(2,4,6-trimethyl-3-(pyridine-3-yl)phenyl)borane (3TPYMB) and FIr6 on the hole transport layer by the vacuum deposition method. In this case, PPT was doped with the FIr6 so that the FIr6 accounts for approximately 7.5% of the emission layer.

Then, an electron transport layer having a thickness of 10 nm was formed by depositing 3TPYMB on the emission layer by the vacuum deposition method.

After that, an electron injection layer, having a thickness of 20 nm, was formed by photo-depositing 3TPYMB and cesium carbonate (Cs₂CO₃) on the electron transport layer by the vacuum deposition method. In this case, 3TPYMB was doped with the Cs₂CO₃ so that the Cs₂CO₃ accounts for approximately 30% of the electron injection layer.

Then, an Al film, serving as a cathode and having a thickness of 100 nm, was formed by depositing Al on the electron injection layer. An organic EL element was thus prepared.

A current efficiency and a life duration T₅₀ at 1000 cd/m² of the organic EL element thus prepared were measured. As a result, good values were obtained, i.e., the current efficiency was 8 cd/A and the life duration T₅₀ was 800 h.

In Examples 1 and 2 above described, the emission layer is made of a host material which has been selected by taking into consideration a phosphorescent material with which the emission layer is doped. Specifically, in Example 1, the CzSi, which has a highest occupied molecular orbital (HOMO) shallower than that of the FIr6, is used as the host material. The TAPC, of which the hole transport layer is made, has a LUMO shallower than that of each of the FIr6 and the CzSi. This allows further prevention of positive holes, which have been transported via the hole transport layer, from being moved to the electron transport layer. Similarly, the 3TPYMB, of which the electron transport layer is made, has a HOMO deeper than that of each of the FIr6 and the CzSi. This allows prevention of electrons, which have been transported via the electron transport layer, from being moved to the hole transport layer. With the configuration, it is possible to (i) reduce positive holes which are moved to the electron transport layer without recombining with electrons and (ii) reduce electrons which are moved to the hole transport layer without recombining with positive holes. This causes positive holes and electrons to be confined within the emission layer, and therefore positive holes become more likely to recombine with electrons. This is the reason why the organic EL element of Example 1 showed the good current efficiency and the good life duration T₅₀.

Here, each of an electron moving speed and a hole moving speed can be expressed by a general Arrhenius' equation (1) below, where “k_{ET}” is a moving speed constant of each of an electron and a positive hole and “A” is a frequency factor (which is independent of temperature).

k_{ET}=Aexp(−ΔE/RT) (1)

When a reaction between molecules is discussed, “A” is considered to represent 10¹¹M⁻¹s⁻¹ (see Non Patent Literature 2). The following list shows moving speed constants found by the equation (1) for respective values of ΔE.

k_{ET}=2.0×10⁹ s⁻¹ for ΔE=0.1 eV.

k_{ET}=4.1×10⁷ s⁻¹ for ΔE=0.2 eV.

k_{ET}=8.4×10⁵ s⁻¹ for ΔE=0.3 eV.

k_{ET}=1.7×10⁴ s⁻¹ for ΔE=0.4 eV.

k_{ET}=3.5×10² s⁻¹ for ΔE=0.5 eV.

k_{ET}=7.1 s⁻¹ for ΔE=0.6 eV.

This shows that, when the ΔE is 0.5 eV or less, an electron is moved, within sub-millisecond (e.g., 29 milliseconds for ΔE=0.5 eV), between molecules from a host material of a first emission layer to a phosphorescent material. In contrast, it is also shown that the electron is moved on the second time scale when the ΔE is 0.6 eV or more. That is, even in a case of an uphill energy difference, an electron can be moved, provided that ΔE is 0.5 eV or less.

Energy f(x), which is stabilized by applying an electric field, can be expressed by an equation (2) below. Specifically, the energy f(x) is energy which causes an electron to be stabilized after the electron is moved, by a distance x, in response to an applied electric field V. Note that “q” is an elementary electric charge (i.e., an absolute value of an electric charge of an electron).

f(x)=−qVx (2)

The equation (2) clearly shows that, since an electric field is applied, an electron (or a positive hole) (i) is hardly moved in a direction opposite to an applied electric field and (ii) is more likely to be merely moved along a gradient of the electric field. It follows that, once a positive hole is affected by an applied electric field so as to be moved, the hole (i) is hardly returned from the first emission layer to an anode side material such as a hole transporting material and (ii) is predominantly moved from a host material of the first emission layer to a phosphorescent material with which the first emission layer is doped.

Therefore, in a case where a difference is not more than 0.5 eV between a HOMO of a host material of the first emission layer and a HOMO of the phosphorescent material, the probability that a positive hole can be thermally excited is increased, and therefore positive holes become more likely to recombine with electrons. Since a difference is more than 0 eV between the HOMO of the host material of the first emission layer and the HOMO of the phosphorescent material, it is possible to reduce a difference between the HOMO of and the LUMO of the host material itself.

Meanwhile, according to Example 2, the hole injection layer is made of TAPC, which is used also in Example 1. Moreover, the hole transport layer is made of the mCP which has a HOMO in (i) between the TAPC and the FIr6 or (ii) between the TAPC and the 3TPYMB. This allows positive holes to be efficiently transported to the emission layer. Moreover, according to Example 2, the 3TPYMB, which has a LUMO deeper than that of the FIr6, is used as the host material of the emission layer. Further, the electron injection layer is doped with the Cs₂CO₃ as an n-dopant. This allows an electron-injection from the cathode to be facilitated. Note that the electron transport layer, which is made of the 3TPYMB, is provided between (i) the electron injection layer, which is doped with the n-dopant, and (ii) the emission layer. This allows prevention of the organic EL element from being deteriorated by a contact of the n-dopant with the emission layer. As such, electrons can be efficiently transported to the emission layer, and therefore it becomes possible to increase the probability that positive holes recombine with electrons. This is the reason why the organic EL element of Example 2 showed the good current efficiency and the good life duration T₅₀. In Example 2, the electron transport layer is made of a material which is identical with the host material of the emission layer. Note, however, that, even in a case where the electron transport layer is made of a material different from that of the host material of the emission layer, it is possible to bring out effects similar to those of Example 2.

### INDUSTRIAL APPLICABILITY

The present invention can be used in various devices each of which includes an organic EL element. For example, the present invention can be used in a display device such as a television.

### REFERENCE SIGNS LIST

1, 1a, 1b, 21, and 31: Organic EL element
2, 22, and 32: Anode
3 and 30: Cathode
4 and 34: Hole transport layer
5, 25, and 35: Emission layer
6 and 36: Electron transport layer
8, 28, and 38: Highest occupied molecular orbital of phosphorescent material
9, 29, and 39: Lowest unoccupied molecular orbital of phosphorescent material
25a: First emission layer
25b: Second emission layer
23 and 33: Hole injection layer
27 and 37: Electron injection layer

1. An organic electroluminescence element comprising:
an anode and a cathode;
a substrate; and
an organic layer, provided between the anode and the cathode, which includes at least an emission layer made of a host material which is doped with an organic light emitting material, the organic layer including:
a hole transport layer, provided between the anode and the emission layer, for transporting a positive hole which has been injected to the organic layer from the anode, and
an electron transport layer, provided between the cathode and the emission layer, for transporting an electron which has been injected to the organic layer from the cathode,
the host material being a hole-transporting material, and
the host material and the organic light emitting material having (i) respective highest occupied molecular orbitals (HOMOs) and (ii) respective lowest unoccupied molecular orbitals (LUMOs) which satisfy the following relational expressions (1) and (2):
0 eV<(|HOMO of organic light emitting material|−|HOMO of host material|)≦0.5 eV (1)

|LUMO of host material|<|LUMO of organic light emitting material|

2. The organic electroluminescence element as set forth in claim 1, wherein:
a material of the electron transport layer, the host material, and the organic light emitting material have respective highest occupied molecular orbitals (HOMOs) which satisfy the following relational expressions (3) and (4):
0.5 eV<(|HOMO of material of electron transport layer|−|HOMO of host material|) (3)
0.5 eV<(|HOMO of material of electron transport layer|−|HOMO of organic light emitting material|) (4)

3. The organic electroluminescence element as set forth in claim 1, wherein:
the material of the electron transport layer has an excited triplet energy level (i) which is higher than that of the organic light emitting material or (ii) which is lower, by 0.1 eV or less, than that of the organic light emitting material.

4. The organic electroluminescence element as set forth in claim 1, wherein:
the material of the electron transport layer has a hole mobility (μ_{H}) which satisfies the following relational expression (5):
μ_{H}≦1.0×10⁻⁵ cm²/Vs (5)

5. An organic electroluminescence element comprising:
an anode and a cathode;
a substrate; and
an organic layer, provided between the anode and the cathode, which includes at least an emission layer made of a host material which is doped with an organic light emitting material,
the organic layer including:
a hole transport layer, provided between the anode and the emission layer, for transporting a positive hole which has been injected to the organic layer from the anode, and
an electron transport layer, provided between the cathode and the emission layer, for transporting an electron which has been injected to the organic layer from the cathode,
the host material being an electron-transporting material, and
the host material and the organic light emitting material having (i) respective highest occupied molecular orbitals (HOMOs) and (ii) respective lowest unoccupied molecular orbitals (LUMOs) which satisfy the following relational expressions (6) and (7):
0 eV<(|LUMO of host material|−|LUMO of organic light emitting material|)≦0.5 eV (6)

|HOMO of host material|>|HOMO of organic light emitting material| (7)

6. The organic electroluminescence element as set forth in claim 5, wherein:
a material of the hole transport layer, the host material, and the organic light emitting material have respective lowest unoccupied molecular orbitals (LUMOs) which satisfy the following relational expressions (8) and (9):
0.5 eV<(|LUMO of host material|−|LUMO of material of hole transport layer|) (8)
0.5 eV<(|LUMO of organic light emitting material|−|LUMO of material of hole transport layer|) (9)

7. The organic electroluminescence element as set forth in claim 5, wherein:
the material of the hole transport layer has an excited triplet energy level (i) which is higher than that of the organic light emitting material or (ii) which is lower, by 0.1 eV or less, than that of the organic light emitting material.

8. The organic electroluminescence element as set forth in claim 5, wherein:
the material of the hole transport layer has an electron mobility (μ_{E}) which satisfies the following relational expression (10):
μ_{E}≦1.0×10⁻⁵ cm²/Vs (10)

9. An organic electroluminescence element as set forth in claim 1, further comprising:
a layer (i) which is provided between the hole transport layer and the emission layer and (ii) which is not doped with an organic light emitting material.

10. An organic electroluminescence element as set forth in claim 1, further comprising:
a layer (i) which is provided between the electron transport layer and the emission layer and (ii) which is not doped with an organic light emitting material.

11. The organic electroluminescence element as set forth in claim 1, wherein:
the hole transport layer is doped with a dopant which facilitates transportation of a positive hole.

12. The organic electroluminescence element as set forth in claim 1, wherein:
the electron transport layer is doped with a dopant which facilitates transportation of an electron.

13. The organic electroluminescence element as set forth in claim 1, wherein:
the hole transport layer is made of a material which is identical with the host material.

14. The organic electroluminescence element as set forth in claim 1, wherein:
the electron transport layer is made of a material which is identical with the host material.

15. The organic electroluminescence element as set forth in claim 1, wherein:
the organic light emitting material is a phosphorescent material.

16. An organic electroluminescence display device comprising:
display means in which an organic electroluminescence element recited in claim 1, is provided on a thin film transistor substrate.

17. A method for manufacturing an organic electroluminescence element which comprises an anode and a cathode, a substrate, and an organic layer, provided between the anode and the cathode, which includes at least an emission layer made of a host material which is doped with an organic light emitting material, said method comprising the steps of:
forming the anode on the substrate;
forming, on the anode, a hole transport layer for transporting a positive hole which has been injected to the organic layer from the anode;
forming the emission layer on the hole transport layer;
forming, on the emission layer, an electron transport layer for transporting an electron which has been injected to the organic layer from the cathode; and
forming the cathode on the electron transport layer,
in the forming of the emission layer, a hole-transporting material being used as the host material, the emission layer being formed by use of the host material and the organic light emitting material having (i) respective highest occupied molecular orbitals (HOMOs) and (ii) respective lowest unoccupied molecular orbitals (LUMOs) which satisfy the following relational expressions (11) and (12):
0 eV<(|HOMO of organic light emitting material|−|HOMO of host material|)<0.5 eV (11)

|LUMO of host material|<|LUMO of organic light emitting material| (12)

18. A method for manufacturing an organic electroluminescence element which comprises an anode and a cathode, a substrate, and an organic layer, provided between the anode and the cathode, which includes at least an emission layer made of a host material which is doped with an organic light emitting material, said method comprising the steps of:
forming the anode on the substrate;
forming, on the anode, a hole transport layer for transporting a positive hole which has been injected to the organic layer from the anode;
forming the emission layer on the hole transport layer;
forming, on the emission layer, an electron transport layer for transporting an electron which has been injected to the organic layer from the cathode; and
forming the cathode on the electron transport layer,
in the forming of the emission layer, an electron-transporting material being used as the host material, the emission layer being formed by use of the host material and the organic light emitting material having (i) respective highest occupied molecular orbitals (HOMOs) and (ii) respective lowest unoccupied molecular orbitals (LUMOs) which satisfy the following relational expressions (13) and (14):
0 eV<(|LUMO of host material|−|LUMO of organic light emitting material|)≦0.5 eV (13)

|HOMO of host material|>|HOMO of organic light emitting material| (14)
